(19) United States
(12) Patent Application Publication
(10) Pub. No.: US 2013/0213798 A1
(43) Pub. Date: Aug. 22, 2013

(54) MAGNETRON SPUTTERING DEVICE, METHOD FOR CONTROLLING MAGNETRON SPUTTERING DEVICE, AND FILM FORMING METHOD

(71) Applicant: Tokuo Yoshida, Osaka (JP)

(72) Inventor: Tokuo Yoshida, Osaka (JP)

(73) Assignee: SHARP KABUSHIKI KAISHA, Osaka (JP)

(21) Appl. No.: 13/878,695

(22) PCT Filed: Oct. 17, 2011
(86) PCT No.: PCT/JP2011/005786

§ 371 Date: Apr. 10, 2013

(30) Foreign Application Priority Data
Oct. 22, 2010 (JP) 2010-237359

(51) Int. Cl. C23C 14/35

(52) U.S. Cl. CPC C23C 14/351
USPC 204/192.15; 204/298.08; 204/192.12

(57) ABSTRACT

A magnetron sputtering device is provided with: a target part positioned in such a manner as to face a substrate held by a substrate holding part; a power source that supplies power to the target part; a magnet part that moves back and forth along the rear of the target part; a chamber having side walls that are electrically grounded; and a power source control part that controls the power source in such a manner that, while the magnet part is away from approach points, which are points respectively closest to the side walls, a prescribed voltage is applied to the target part by the power source, but the prescribed voltage is reduced when the magnet part reaches one of the approach points.

### TECHNICAL FIELD

The present invention relates to a magnetron sputtering device, a method for controlling the magnetron sputtering device, and a film forming method.

### BACKGROUND ART

The sputtering method is widely known as a dry process technique indispensable in film forming techniques. The sputtering method is a method for forming films in which a noble gas such as Ar gas is introduced into a vacuum container, and direct current (DC) power or radio frequency (RF) power is supplied to a cathode that includes a target, thus generating a glow discharge. The former is referred to as DC sputtering, and the latter is referred to as RF sputtering.

The sputtering method includes the magnetron sputtering method in which a magnet is disposed on the rear of a target in an electrically grounded chamber, which increases the concentration of plasma in the vicinity of the target surface, thereby allowing film forming to be conducted quickly. The magnetron sputtering method includes the RF magnetron sputtering method that uses RF power and the DC magnetron sputtering method that uses DC power, and both are used as high volume production methods for film forming.

In recent years, technical development for improving thin film characteristics is sought in film forming techniques involving magnetron sputtering. Factors that inhibit thin film characteristics when forming a film using the sputtering method include damage to the thin film due to high energy particles impacting a substrate. The energy of the high energy particles mainly results from a difference in potential that occurs on the front surface of the target, and thus, in order to attain a high quality thin film, the difference in potential needs to be made small.

An RF-DC coupled magnetron sputtering method in which sputtering is conducted by simultaneously supplying RF power and DC power to the cathode is also known. The RF-DC coupled magnetron sputtering method can control the VT (the average potential over time of the cathode surface, which is the target surface) by the voltage of the DC power source that supplies DC power. Therefore, in the RF-DC coupled magnetron sputtering method, by increasing the VT, it is possible to decrease the difference in potential on the front surface of the target, which allows a high quality thin film to be formed.

However, in the magnetron sputtering method, there is a problem that a special type of abnormal discharge (tracking arc) occurs, in which the arc rotates on parts of the target where there are zero components of the magnetic field perpendicular to the target surface (in other words, parts of the target that are etched the most). As the tracking arc occurs, the discharge impedance changes and power is not supplied efficiently to the target, which results in an undesirable situation in which the film forming speed decreases, or the film is not formed at all.

In order to deal with this, Patent Document 1 discloses a thin film forming method using the RF-DC coupled magnetron sputtering method in which an attempt is made to prevent the occurrence of tracking arcs by stopping the supply of RF power and DC power to the target simultaneously and periodically, and by shortening the amount of time in which power is supplied to less than the amount of time required for tracking arcs to occur.

Patent Document 2 discloses a technique of moving the magnet along a perpendicular direction to the target surface depending on fluctuations in magnetron discharge voltage in the magnetron sputtering method in which the magnet is moved, thus maintaining a substantially uniform discharge voltage.

### RELATED ART DOCUMENTS

### Patent Documents

Patent Document 1: Japanese Patent Application Laid-Open Publication No. H11-6063
Patent Document 2: Japanese Patent Application Laid-Open Publication No. 2000-144408

### SUMMARY OF THE INVENTION

### Problems to be Solved by the Invention

The inventor of the present invention, upon conducting diligent studies of a magnetron sputtering device, has discovered that when an oscillating magnet approaches a side wall of an electrically grounded chamber, as shown in the graphs in FIGS. 7 and 8, fluctuation occurs in the discharge voltage, which causes abnormal discharge.

The method disclosed in Patent Document 1 relates to a countermeasure against arcs, and does not disclose or teach any techniques for abnormal discharge voltage due to magnet oscillation or resulting changes in film quality or uniformity in film quality. The sputtering device disclosed in Patent Document 2 has a problem that the mechanism for oscillating the magnet is very complex.

The present invention takes into consideration such issues, and an object thereof is to mitigate the occurrence of abnormal discharge voltage due to oscillations of a magnet part in a magnetron sputtering device in which the magnet part oscillates along a surface of a target part, thereby improving the quality of a thin film formed on a substrate.

### Means for Solving the Problems

In order to achieve the above-mentioned object, a magnetron sputtering device according to the present invention includes: a substrate holding part that holds a substrate; a target part disposed so as to face the substrate held by the substrate holding part; a power source that supplies power to the target part; a magnet part that is disposed on a rear side of the target part, the rear side being a side of the target part opposite to the substrate, the magnet part moving back and forth along the rear side of the target part; and a chamber with electrically grounded side walls that stores the substrate holding part, the target part, the power source, and the magnet part therein.

The magnetron sputtering device also includes a power source control part that controls the power source such that when the magnet part is away from approach points, the approach points being points respectively closest to the side walls of the chamber, a prescribed voltage is applied from the power source to the target part, and when the magnet part reaches one of the approach points, the prescribed voltage is decreased.

### Effects of the Invention

According to the present invention, a prescribed voltage is applied to the target part from the power source while the magnet part is away from the approach points, which are points respectively closest to the side walls of the chamber, and the prescribed voltage is decreased when the magnet part reaches one of the approach points, and thus, even when the magnet part reaches an approach point, it is possible to mitigate abnormal discharge voltage in the chamber. As a result, it is possible to greatly improve the quality of the thin film formed on the substrate.

### BRIEF DESCRIPTION OF THE DRAWINGS

FIG. 1 is a cross-sectional view that shows a schematic configuration of a magnetron sputtering device of Embodiment 1.

FIG. 2 is a plan view that shows a target part in Embodiment 1.

FIG. 3 is a graph that shows a waveform of a cathode voltage in a case in which a power source is controlled in Embodiment 1.

FIG. 4 is a graph that shows a waveform of a cathode voltage in a case in which a power source is not controlled.

FIG. 5 is a graph that schematically shows a magnified portion of FIG. 4.

FIG. 6 is a descriptive drawing that shows a relation between regions with defective film quality that occur when the power source is not controlled, and targets and magnets.

FIG. 7 is a graph that shows an abnormal discharge voltage that occurs when the power source is not controlled.

FIG. 8 is a graph that shows an abnormal discharge voltage that occurs when the power source is not controlled.

FIG. 9 is a cross-sectional view that shows a schematic configuration of a magnetron sputtering device of Embodiment 2.

FIG. 10 is a plan view that shows a positional relation between a magnet part and a substrate of Embodiment 2.

FIG. 11 is a plan view that shows a positional relation between the magnet part and regions of a substrate where defects in film quality have occurred.

FIG. 12 is a graph that shows a waveform of a cathode voltage in a case in which a power source is not controlled.

FIG. 13 is a graph that shows a waveform of a cathode voltage in a case in which a power source is controlled in Embodiment 2.

FIG. 14 is a graph that shows a waveform of a cathode voltage in a case in which a power source is not controlled.

FIG. 15 is a graph that shows a waveform of a cathode voltage in a case in which a power source is controlled in Embodiment 2.

FIG. 16 is a cross-sectional view that shows a schematic configuration of a magnetron sputtering device of Embodiment 3.

FIG. 17 is a plan view that shows a positional relation between a magnet part and a substrate of Embodiment 3.

FIG. 18 is a plan view that shows a positional relation between the magnet part and regions of a substrate where defects in film quality have occurred.

### DETAILED DESCRIPTION OF EMBODIMENTS

Embodiments of the present invention will be described in detail below with reference to drawings. The present invention is not limited to the embodiments below.

### Embodiment 1

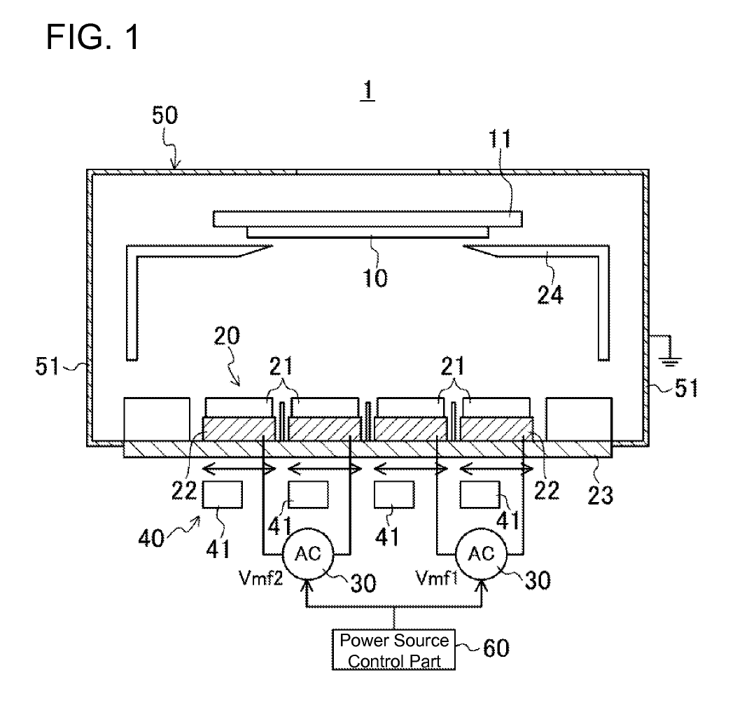

FIGS. 1 to 8 show Embodiment 1 of the present invention.

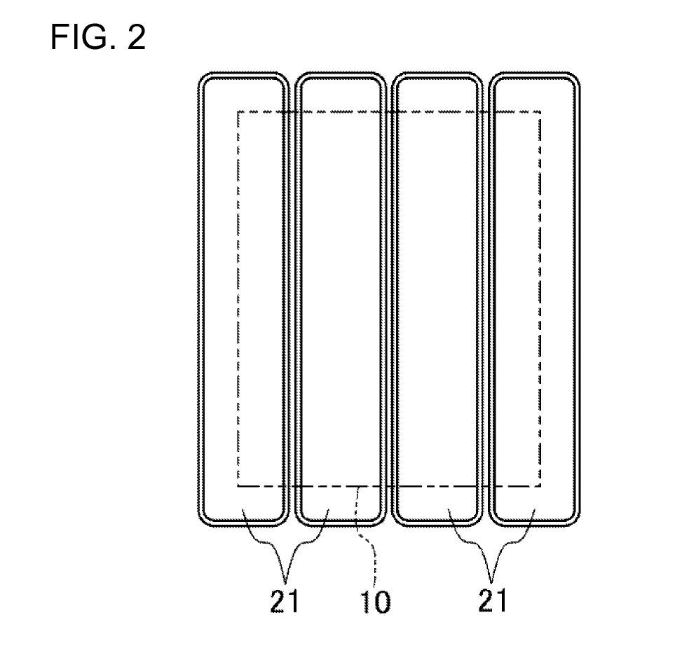

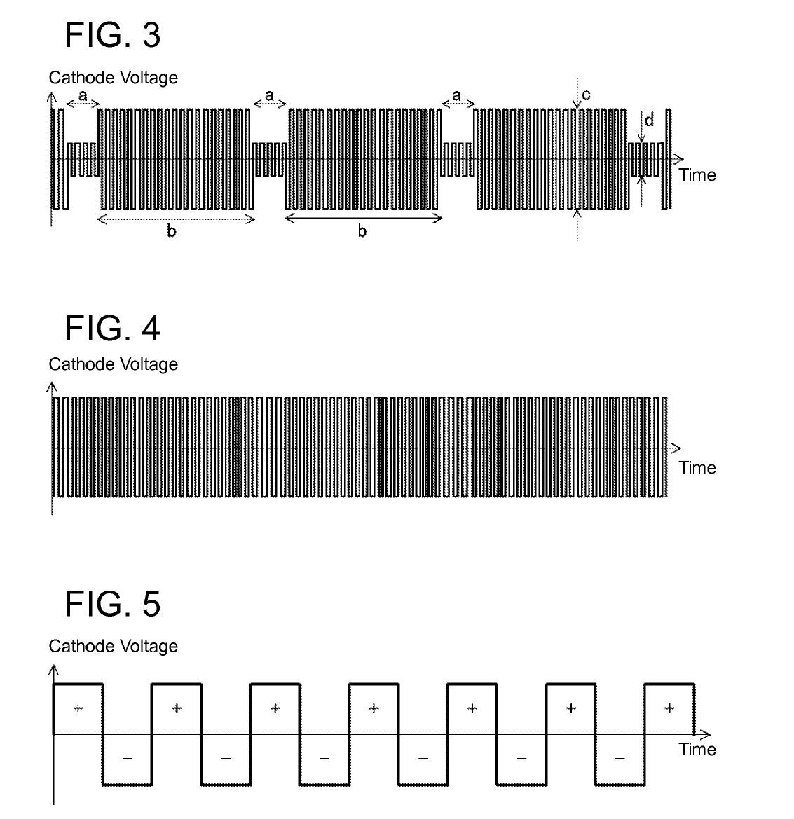

FIG. 1 is a cross-sectional view that shows a schematic configuration of a magnetron sputtering device 1 of Embodiment 1. FIG. 2 is a plan view that shows a target part 20 in Embodiment 1. FIG. 3 is a graph that shows a waveform of a cathode voltage in a case in which a power source is controlled in Embodiment 1.

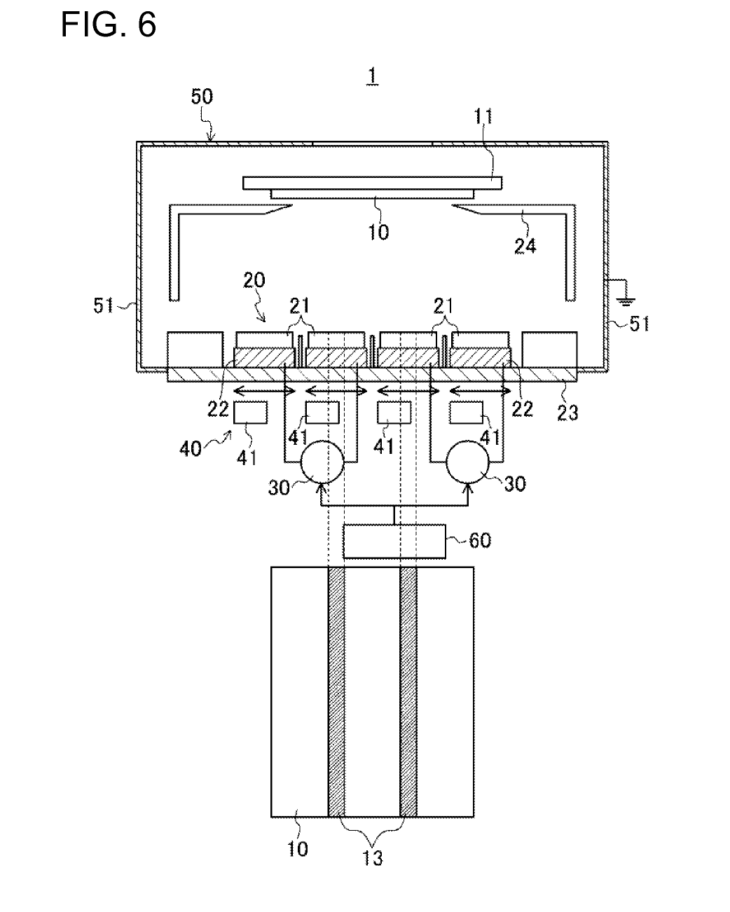

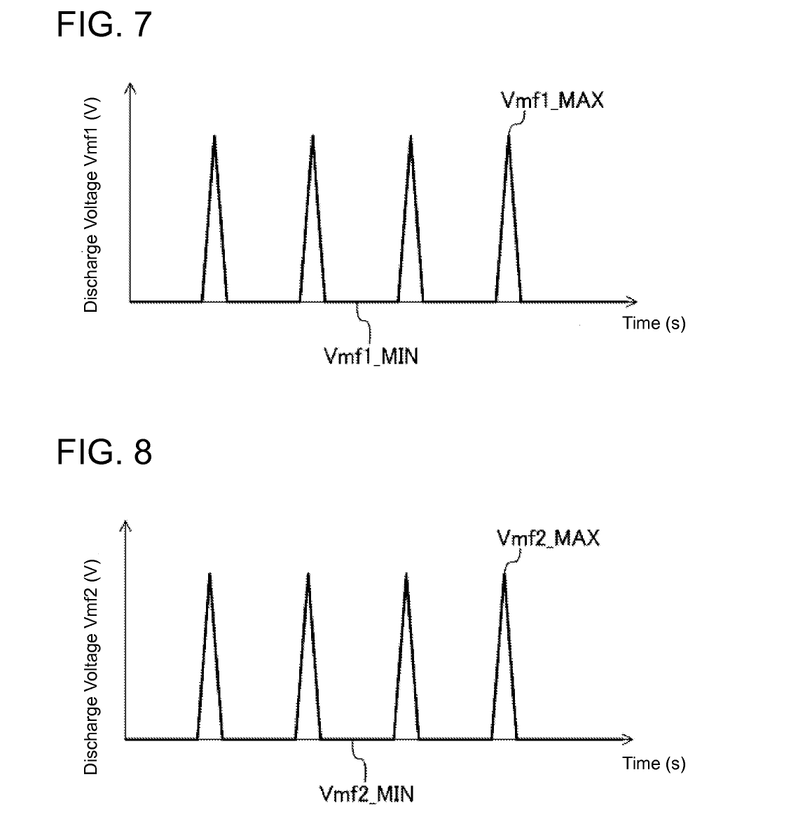

FIG. 4 is a graph that shows a waveform of a cathode voltage in a case in which a power source is not controlled. FIG. 5 is a graph that schematically shows a magnified portion of FIG. 4. FIG. 6 is a descriptive drawing that shows a relation between regions with defective film quality that occur when the power source is not controlled, and targets 21 and magnets 41. FIGS. 7 and 8 are graphs that show abnormal discharge voltages that occur when the power source is not controlled.

As shown in FIG. 1, the magnetron sputtering device 1 of Embodiment 1 includes a substrate holding part 11 that holds a substrate 10, a target part 20 disposed so as to face the substrate 10 held by the substrate holding part 11, power sources 30 that supply power to the target part 20, a magnet part 40 that is disposed on the rear side of the target part 20, which is the side of the target part 20 opposite to the substrate 10, and a chamber 50 that stores the substrate holding part 11, the target part 20, the power sources 30, and the magnet part 40 therein.

The chamber 50 is a vacuum chamber in which the side walls 51 thereof are electrically grounded. A vacuum pump not shown in the drawing is connected to the chamber 50, and the inside the chamber 50 is depressurized by the vacuum pump. The chamber 50 is also provided with a gas supply part (not shown in drawing). The gas supply part is configured to introduce Ar gas and, if necessary, O₂ gas into the chamber 50, when the chamber 50 is in a vacuum state.

The substrate 10 is a glass substrate or the like of a liquid crystal display panel (not shown in drawing), for example. The substrate 10 has a vertical length of 730 mm and a horizontal length of 920 mm, for example. The substrate holding part 11 holds the substrate 10 on the lower surface thereof, and has a heater (not shown in drawing) that heats the substrate 10 when conducting film forming. Substrate masks 24 that cover outer edges of the lower surface of the substrate 10 are provided in the chamber 50.

As shown in FIGS. 1 and 2, the target part 20 has four rectangular plate-shaped targets 21, for example. The four targets 21 all have the same shape, and are aligned in a prescribed direction (the left/right direction in FIGS. 1 and 2) in which the long sides are adjacent to each other. The targets 21 are respectively disposed with a prescribed gap therebetween in the movement direction of the magnet part 40, which will be described later.

The targets 21 are made of a material that includes IGZO (In—Ga—ZnO₄; amorphous oxide semiconductor), for example. The target part 20 is supported by target support parts 22. The target support parts 22 are made of a conductive material such as a metal, for example. The target support parts 22 are disposed on an insulating member 23. The target support parts 22 are connected to two power sources 30.

The power sources 30 are AC power sources, and as shown in FIGS. 4 and 5, apply a prescribed alternating current drive voltage to the target part 20 through the target support parts 22. The frequency of the drive voltage (cathode voltage) of the power sources 30 is approximately 19 kHz to 20 kHz, for example.

The magnet part 40 is configured to travel back and forth along the rear side of the target part 20 by a drive mechanism not shown in the drawing. As shown in FIG. 1, the magnet part 40 has a plurality of magnets 41 disposed with a prescribed gap therebetween in the movement direction of the magnet part 40 (left/right direction in FIG. 1).

As shown in FIG. 1, the magnets 41 oscillate in synchronization with each other. The oscillation speed is approximately 10 mm/s to 30 mm/s, for example. The oscillation amplitude of each magnet 41 is substantially the same as the width of each target 21 (in other words, the width in the movement direction of the magnet part 40). The width of the magnet 41 is less than the width of the target 21. The width of the magnet 41 is approximately half the width of the target 21, for example.

The magnetron sputtering device 1 has a power source control part 60 that controls the output from the power sources 30. The power source control part 60 controls the power sources 30 so as to apply a prescribed voltage to the target part 20 while the magnet part 40 is away from approach points, which are points respectively closest to the side walls 51 of the chamber 50, and so as to lower the prescribed voltage when the magnet part 40 reaches an approach point.

In other words, when the magnet part 40 has not reached the position facing the left or right edge of the target part 20 and is therefore away from an approach point, then as shown in FIG. 3 with the reference character “c”, the power source control part 60 sets the input power density of the power sources 30 at 1.0 W/cm² to 4.0 W/cm², and as shown in FIG. 3 with the reference character “b”, the power source control part 60 maintains this state for approximately 4 s to 15 s according to the oscillation speed of the magnet part 40.

When the magnet part 40 reaches an approach point to each side wall 51 by moving to a position facing either the left or right edge of the target part 20, then as shown in FIG. 3 with the reference character “d”, the power source control part 60 sets the input power density of the power sources 30 to a prescribed value that is less than 1.0 W/cm² while still maintaining electric discharge, and as shown in FIG. 3 with the reference character “a”, the power source control part 60 maintains this state for approximately 1 ms, for example.

The power source control part 60 may also stop applying voltage to the target part 20 from the power sources 30 when the magnet part 40 reaches an approach point.

—Control Method and Film Forming Method—

Next, a control method and a film forming method of the magnetron sputtering device 1 will be described.

When film forming is conducted on the substrate 10 by the magnetron sputtering device 1, first, the substrate 10, which is a glass substrate, is brought into the chamber 50 and held by the substrate holding part 11. Next, the inside of the chamber 50 is depressurized by a vacuum pump (not shown in drawing), and the substrate 10 is heated by a heater (not shown in drawing) in the substrate holding part 11. The target 21 is made of a material that includes IGZO (In—Ga—ZnO₄; amorphous oxide semiconductor), for example.

Next, while maintaining a high vacuum state, a gas supply part (not shown in drawings) introduces Ar gas and, as necessary, O₂ gas into the chamber 50. Then, power is supplied to the target part 20 by applying a prescribed alternating current voltage from the power sources 30, and the magnet part 40 is oscillated, thus starting film forming. The oscillation speed of the magnet part 40 is approximately 10 mm/s to 30 mm/s, for example.

The voltage applied to the target part 20 is controlled by the power source control part 60. In other words, as shown in FIG. 3, while the magnet part 40 is away from approach points (approximately 4 s to 15 s based on the oscillation speed of the magnet part 40, for example), which are points respectively closest to the side walls 51 of the chamber 50, a voltage with an input power density of approximately 1.0 W/cm² to 4.0 W/cm² is applied to the target part 20 from the power sources 30.

By generating a glow discharge between the target part 20 and a wall of the chamber 50, plasma is generated on the substrate 10 side of the target part 20. Ar that has become positively ionized due to the plasma is drawn to the target part 20. The Ar ions collide with each target 21 causing particles that constitute the target 21 to fly off and bond to the substrate 10. With this process, a film is formed on a surface of the substrate 10.

Here, when the voltage of the power sources 30 is maintained at a constant prescribed input power density as stated above, then as shown in FIGS. 7 and 8, an abnormal discharge voltage is generated in the discharge voltage of each of the two power sources 30, which means that the discharge voltage periodically increases by approximately 10% compared to a constant discharge voltage. When actually measured, a constant discharge voltage Vmf1_MIN of one of the power sources 30 was 525V, and an abnormal discharge voltage thereof. Vmf1_MAX was 583V. The constant discharge voltage Vmf2_MIN of the other power source 30 was 545V, and the abnormal discharge voltage thereof. Vmf2_MAX was 609V.

The abnormal discharge voltage occurs when the magnet part 40 reaches an approach point to each side wall 51 of the chamber 50. As shown in FIG. 6, due to the abnormal discharge, the film quality at the substrate 10 changes in regions 13 at the centers of the oscillation direction of the magnets 41.

In order to deal with this, in the present embodiment, the voltage of the power sources 30 is controlled by the power source control part 60 such that the voltage of the power sources 30 when the magnet part 40 reaches an approach point is less than the voltage when the magnet part 40 is away from an approach point. In other words, as shown in FIG. 3, the input power density of the power sources 30 is set to a prescribed value of less than 1.0 W/cm² while maintaining electrical discharge, and this state is maintained for approximately 1 ms, for example. In this manner, voltage control of the power sources 30 is conducted periodically to match the position of the magnet part 40. As a result, the discharge voltage when the magnet part 40 reaches an approach point can be appropriately decreased, and the discharge voltage can be maintained at a substantially constant level.

### Effects of Embodiment 1

Therefore, according to Embodiment 1, when the magnet part 40 is away from approach points, which are points respectively closest to the side walls 51 of the chamber 50, a prescribed voltage is applied to the target part 20 from the power sources 30, but when the magnet part 40 has reached an approach point, the prescribed voltage is lowered, and thus, even when the magnet part 40 has reached an approach point, it is possible to mitigate abnormal discharge voltage in the chamber 50 by appropriately decreasing the discharge voltage. As a result, it is possible to increase the uniformity of the thin film formed on the substrate 10, and to greatly improve the film quality thereof.

### Embodiment 2

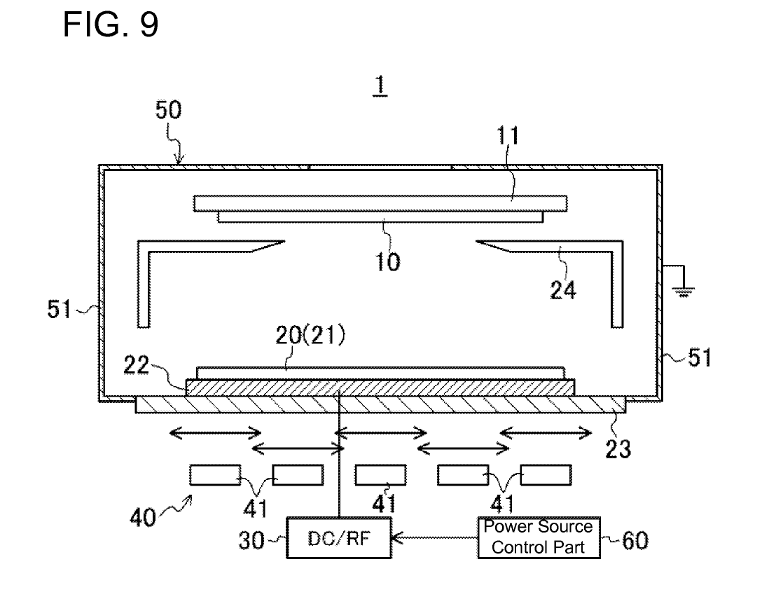

FIGS. 9 to 15 show Embodiment 2 of the present invention.

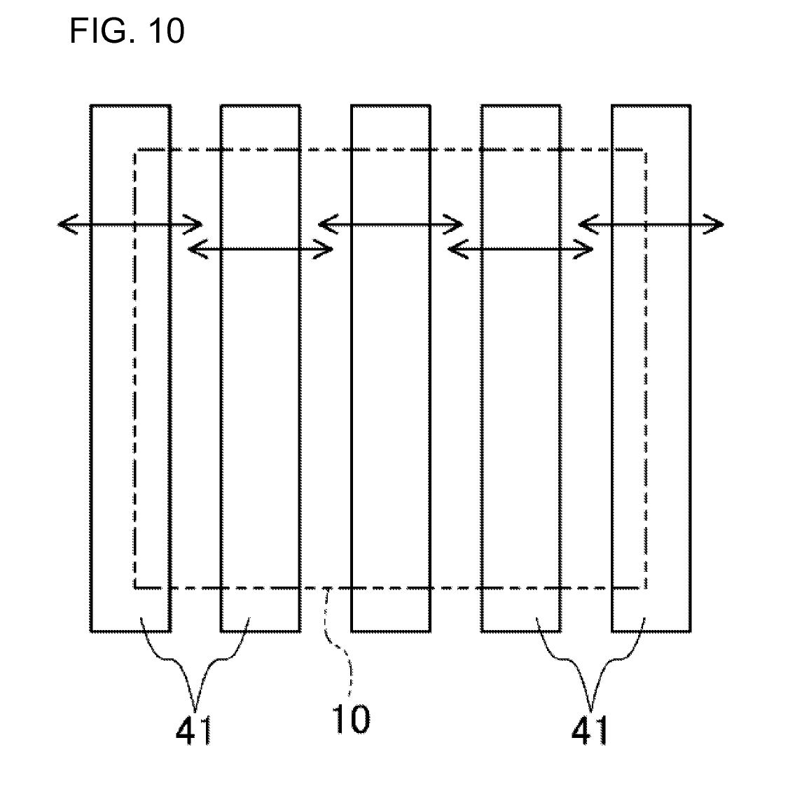

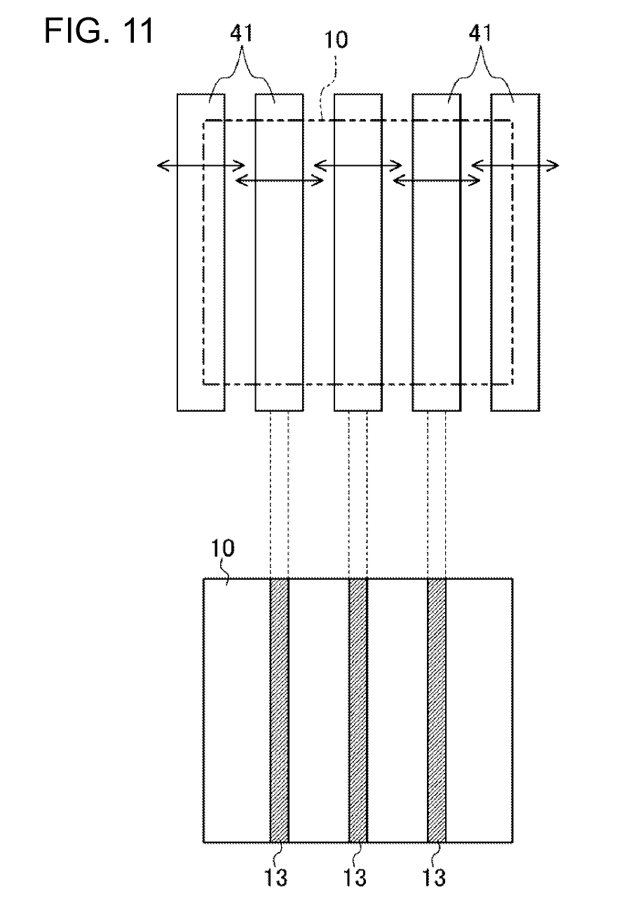

FIG. 9 is a cross-sectional view that shows a schematic configuration of a magnetron sputtering device 1 of Embodiment 2. FIG. 10 is a plan view that shows a positional relation between a magnet part 40 and a substrate 10 in Embodiment 2. FIG. 11 is a plan view that shows a positional relation between the magnet part 40 and regions of the substrate 10 where defects in film quality have occurred.

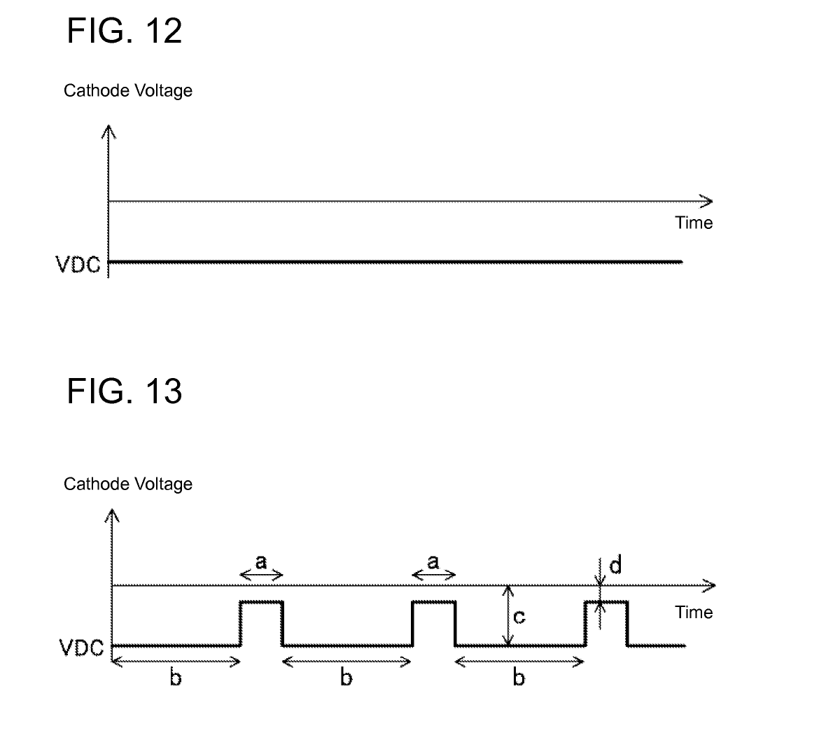

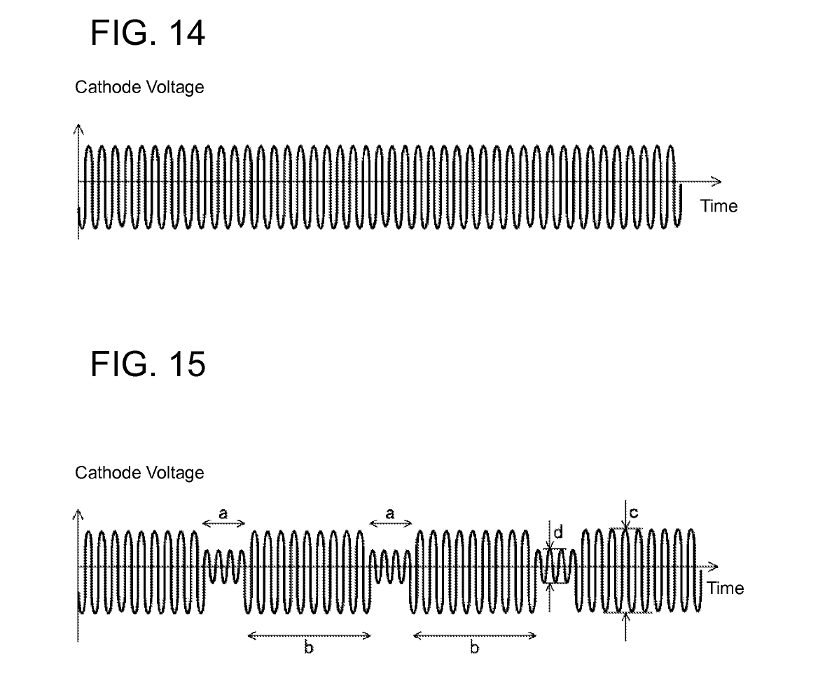

FIGS. 12 and 14 are graphs that show waveforms of cathode voltages in a case in which a power source is not controlled. FIGS. 13 and 15 are graphs that show waveforms of cathode voltages in a case in which a power source is controlled in Embodiment 2. As for the embodiments below, parts that are the same as FIGS. 1 to 8 are assigned the same reference characters and detailed descriptions thereof will be omitted.

In Embodiment 1, the target part 20 has a plurality of targets 21 and the power sources 30 are AC power sources, whereas Embodiment 2 has a target part 20 constituted of one target, and a power source 30 is a DC power source or an RF power source.

In other words, as shown in FIG. 9, the magnetron sputtering device 1 of the present embodiment has a substrate holding part 11, substrate masks 24, an insulating member 23, and a target support part 22 inside a chamber 50, as in Embodiment 1.

In the present embodiment, the target part 20 supported by the target support part 22 is constituted of one target. The magnet part 40 is disposed on the rear side of the target part 20 and has a plurality of magnets 41 that move parallel to the rear side of the target part 20. The substrate 10 has a vertical length of 404 mm and a horizontal length of 595 mm, for example.

If the power source 30 is a DC power source, when the magnet part 40 has not reached a position facing a left or right edge of the target part 20 and is away from an approach point to a side wall 51 of the chamber 50, then as shown in FIG. 13 with the reference character “c”, a power source control part 60 sets the power source 30 such that the input power density thereof is approximately 0.3 W/cm² to 1.6 W/cm², and as shown in FIG. 13 with the reference character “b”, the power source control part 60 maintains this state for approximately 10 s to 20 s based on the oscillation speed of the magnet part 40.

On the other hand, if the magnet part 40 has reached an approach point to a side wall 51 by moving to a position facing either the left or right edge of the target part 20, then as shown in FIG. 13 with the reference character “d”, the input power density of the power source 30 is set to a prescribed value of less than 0.3 W/cm² while maintaining electrical discharge, and as shown in FIG. 13 with the reference character “a”, this state is maintained for 1 ms, for example. The power source control part 60 may stop applying voltage to the target part 20 from the power source 30 when the magnet part 40 reaches an approach point.

If the power source 30 is an RF power source, when the magnet part 40 is away from an approach point, then as shown in FIG. 15 with the reference character “c”, the power source control part 60 sets the input power density of the power source 30 to approximately 0.3 W/cm² to 4.0 W/cm², and as shown in FIG. 15 with the reference character “b”, the power source control part 60 maintains this state for approximately 4 s to 20 s based on the oscillation speed of the magnet part 40.

On the other hand, if the magnet part 40 has reached an approach point, then as shown in FIG. 15 with the reference character “d”, the input power density of the power source 30 is set to a prescribed value of less than 0.3 W/cm² while maintaining electrical discharge, and as shown in FIG. 13 with the reference character “a”, this state is maintained for approximately 1 ms, for example. The power source control part 60 may stop applying voltage to the target part 20 from the power source 30 when the magnet part 40 reaches an approach point.

—Control Method and Film Forming Method—

Next, a control method and a film forming method of the magnetron sputtering device 1 will be described.

When conducting film forming on the substrate 10 using the magnetron sputtering device 1, the substrate 10 brought into the chamber 50 is held by the substrate holding part 11, the inside of the chamber 50 is depressurized, and the substrate 10 is heated by a heater (not shown in the drawing), similar to Embodiment 1.

Next, while maintaining a high vacuum, Ar gas and, as necessary, O₂ gas are introduced into the chamber 50, and the target part 20 is supplied with power by applying a prescribed direct current voltage from the power source 30, and the magnet part 40 is oscillated, thus starting film forming.

First, if the power source 30 is a DC power source, the oscillation speed of the magnet part 40 is approximately 4 mm/s to 10 mm/s, for example. The voltage applied to the target part 20 is controlled by the power source control part 60. In other words, as shown in FIG. 13, while the magnet part 40 is away from approach points (approximately 10 s to 20 s based on the oscillation speed of the magnet part 40, for example), which are points respectively closest to the side walls 51 of the chamber 50, a voltage with an input power density of approximately 0.3 W/cm² to 1.6 W/cm² is applied to the target part 20 from the power source 30.

In this way, Ar ions are caused to collide with the target 21 by the plasma formed on the substrate 10 side of the target part 20, thus forming a film on the surface of the substrate 10.

Here, when the voltage of the power source 30 is maintained at a constant prescribed input power density as shown in FIG. 12, then as shown in FIG. 11, an abnormal discharge occurs when the magnet part 40 reaches an approach point to a side wall 51, and the film quality of the substrate 10 changes in the oscillation range of each of the oscillating magnets 41 where the effect of the abnormal discharge accumulates (in other words, as shown in FIG. 11, regions 13 in the centers of the oscillation direction of the respective magnets 41).

In order to deal with this, in the present embodiment, the voltage of the power source 30 is controlled by the power source control part 60 such that the voltage of the power source 30 when the magnet part 40 reaches an approach point is less than the voltage when the magnet part 40 is away from an approach point. In other words, as shown in FIG. 13, the input power density of the power source 30 is set to a prescribed value of less than 0.3 W/cm² while maintaining electrical discharge, and this state is maintained for approximately 1 ms, for example. Also, the power source control part 60 may set the power source 30 to stop applying a voltage to the target part 20 when the magnet part 40 reaches an approach point.

On the other hand, if the power source 30 is an RF power source, the oscillation speed of the magnet part 40 is set to approximately 4 mm/s to 30 mm/s, for example. The voltage applied to the target part 20 is controlled by the power source control part 60. In other words, as shown in FIG. 15, while the magnet part 40 is away from an approach point (4 s to 20 s based on the oscillation speed of the magnet part 40, for example), a voltage with an input power density of approximately 0.3 W/cm² to 4.0 W/cm² is applied to the target part 20 from the power source 30.

In this way, Ar ions are caused to collide with the target 21 by the plasma formed on the substrate 10 side of the target part 20, thus forming a film on the surface of the substrate 10.

Here, if the voltage of the power source 30 is maintained at a constant prescribed input power density as shown in FIG. 14, then as shown in FIG. 11, an abnormal discharge occurs when the magnet part 40 reaches an approach point to a side wall 51, and the film quality of the substrate 10 changes in the oscillation range of each of the oscillating magnets 41 where the effect of the abnormal discharge accumulates (in other words, as shown in FIG. 11, the regions 13 in the centers of the oscillation direction of the magnets 41).

In order to deal with this, in the present embodiment, the voltage of the power source 30 is controlled by the power source control part 60 such that the voltage of the power source 30 when the magnet part 40 reaches an approach point is less than the voltage when the magnet part 40 is away from an approach point. In other words, as shown in FIG. 15, the input power density of the power source 30 is set to a prescribed value of less than 0.3 W/cm² while maintaining electrical discharge, and this state is maintained for approximately 1 ms, for example. Also, the power source control part 60 may set the power source 30 to stop applying a voltage to the target part 20 when the magnet part 40 reaches an approach point.

By controlling the voltage of the power source 30 periodically based on the position of the magnet part 40 in this way, when the magnet part 40 reaches an approach point, the discharge voltage is appropriately decreased, and the discharge voltage can be maintained at a substantially constant level.

### Effects of Embodiment 2

Therefore, in Embodiment 2, as in Embodiment 1, while a prescribed voltage is applied by the power source 30 to the target part 20 when the magnet part 40 is away from an approach point, the prescribed voltage is lowered when the magnet part 40 reaches an approach point, and thus, even when the magnet part 40 reaches an approach point, it is possible to mitigate abnormal discharge voltage in the chamber 50 by appropriately lowering the discharge voltage. As a result, it is possible to increase the uniformity of the thin film formed on the substrate 10, and to greatly improve the film quality thereof.

### Embodiment 3

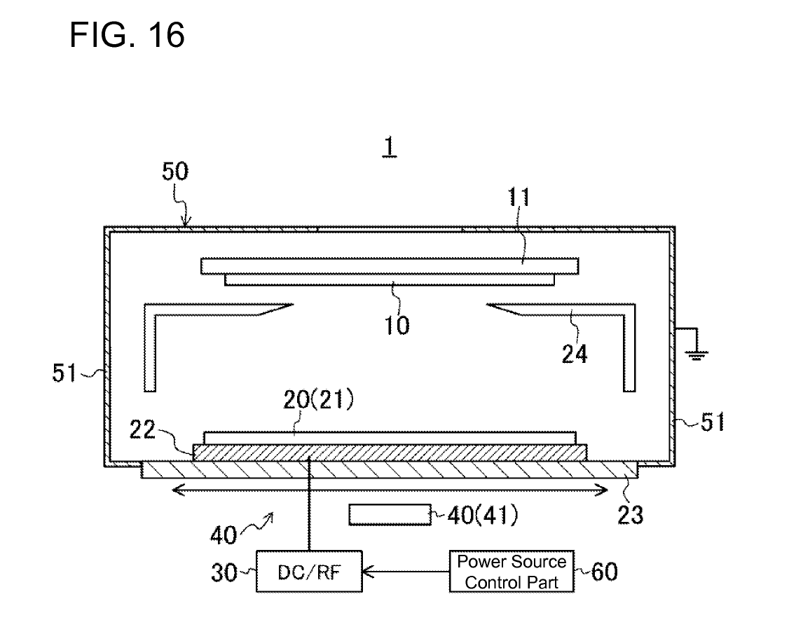

FIGS. 16 to 18 show Embodiment 3 of the present invention.

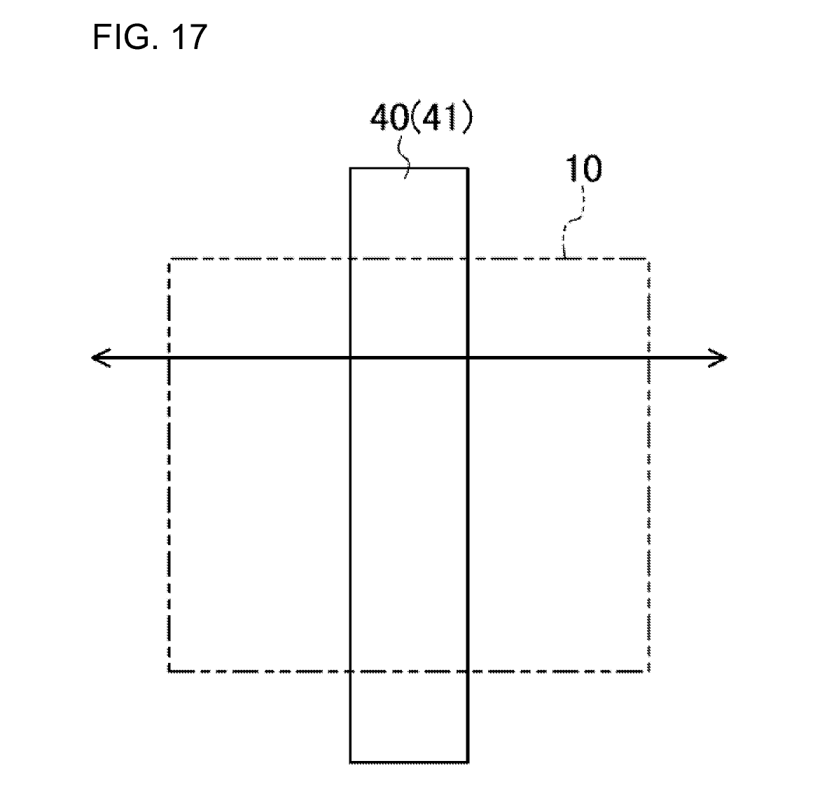

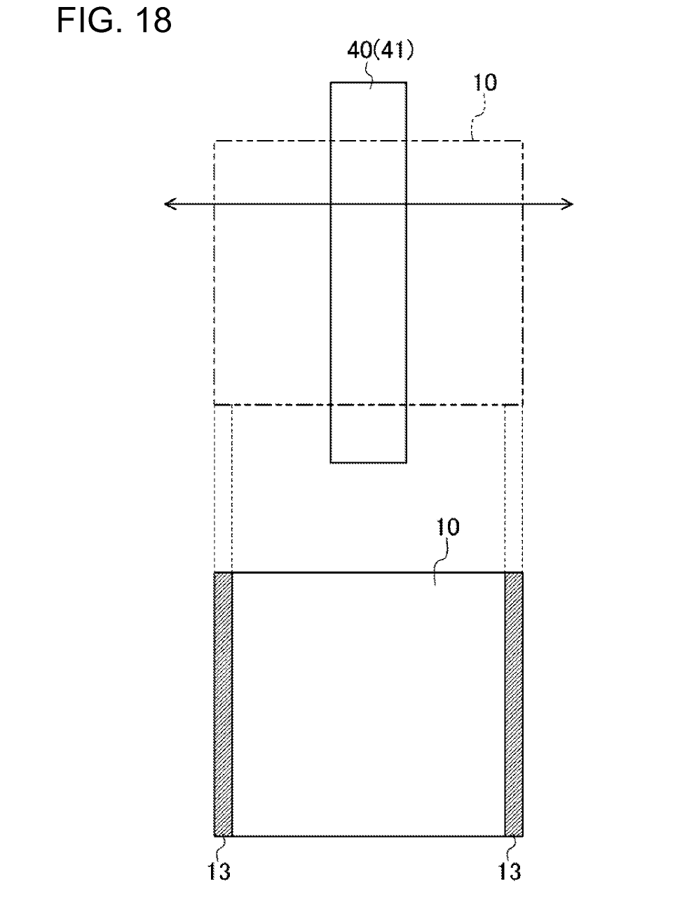

FIG. 16 is a cross-sectional view that shows a schematic configuration of a magnetron sputtering device 1 of Embodiment 3. FIG. 17 is a plan view that shows a positional relation between a magnet part 40 and a substrate 10 in Embodiment 3. FIG. 18 is a plan view that shows a positional relation between the magnet part 40 and regions of the substrate 10 where defects in film quality have occurred.

Embodiment 3 is similar to Embodiment 2, except the magnet part 40 is constituted of one magnet 41.

In other words, as shown in FIG. 16, a magnetron sputtering device 1 of the present embodiment has a substrate holding part 11, substrate masks 24, an insulating member 23, a target part 20, and a target support part 22 inside a chamber 50, as in Embodiment 2.

The magnet part 40 has one magnet 41, which moves back and forth between one edge and the other edge of the target part 20. The substrate 10 has a vertical length of 320 mm and a horizontal length of 400 mm, for example. The power source 30 is a DC power source or an RF power source, as in Embodiment 2.

The power source control part 60 causes a relatively large voltage to be applied to the target part 20 when the magnet part 40 is away from an approach point, as in Embodiment 2. When the magnet part 40 has reached an approach point, then the voltage is lowered as in Embodiment 2.

Here, when power source control by the power source control part 60 is not conducted, then as shown in FIG. 18, an abnormal discharge occurs when the magnet part 40 reaches an approach point, which results in a change in quality in the thin film in regions 13 on the left and right edges of the substrate 10, resulting in a loss of uniformity in the film quality.

In order to deal with this, in Embodiment 3, when the magnet part 40 is away from an approach point, a prescribed voltage is applied from the power source 30 to the target part 20, and when the magnet part 40 reaches an approach point, the prescribed voltage is lowered, and thus, even when the magnet part 40 reaches an approach point, it is possible to appropriately decrease the discharge voltage and mitigate abnormal discharge voltage in the chamber 50, as in Embodiments 1 and 2. As a result, it is possible to increase the uniformity of the thin film formed on the substrate 10, and to greatly improve the film quality thereof.

The present invention is not limited to Embodiments 1 to 3, and includes configurations in which Embodiments 1 to 3 are appropriately combined.

### INDUSTRIAL APPLICABILITY

As described above, the present invention is applicable to a magnetron sputtering device, a method for controlling the magnetron sputtering device, and a film forming method.

### DESCRIPTION OF REFERENCE CHARACTERS

1 magnetron sputtering device
10 substrate
11 substrate holding part
20 target part
21 target
22 target support part
23 insulating member
30 power source
40 magnet part
41 magnet
50 chamber
51 side wall of chamber
60 power source control part

1. A magnetron sputtering device, comprising:
a substrate holding part that holds a substrate;
a target part disposed so as to face the substrate held by the substrate holding part;
a power source that supplies power to the target part;
a magnet part that is disposed on a rear side of the target part, the rear side being a side of the target part opposite to the substrate, the magnet part moving back and forth along the rear side of the target part;
a chamber with electrically grounded side walls that stores the substrate holding part, the target part, the power source, and the magnet part therein; and
a power source control part that controls the power source such that when the magnet part is away from approach points, the approach points being points respectively closest to the side walls of the chamber, a prescribed voltage is applied from the power source to the target part, and when the magnet part reaches one of the approach points, the prescribed voltage is decreased.

2. The magnetron sputtering device according to claim 1, wherein the power source control part stops applying a voltage from the power source to the target part when the magnet part reaches one of the approach points.

3. The magnetron sputtering device according to claim 1, wherein the magnet part has a plurality of magnets disposed with a prescribed gap therebetween in a movement direction of the magnet part.

4. The magnetron sputtering device according to claim 1, wherein the target part has a plurality of targets disposed with a prescribed gap therebetween in a movement direction of the magnet part.

5. A method for controlling a magnetron sputtering device that includes:
a substrate holding part that holds a substrate;
a target part disposed so as to face the substrate held by the substrate holding part;
a power source that supplies power to the target part;
a magnet part that is disposed on a rear side of the target part, the rear side being a side of the target part opposite to the substrate, the magnet part moving back and forth along the rear side of the target part; and
a chamber with electrically grounded side walls that stores the substrate holding part, the target part, the power source, and the magnet part therein,
the method comprising:
controlling the power source such that when the magnet part is away from approach points, the approach points being points respectively closest to the side walls of the chamber, a prescribed voltage is applied from the power source to the target part, and when the magnet part reaches one of the approach points, the prescribed voltage is decreased.

6. The method for controlling a magnetron sputtering device according to claim 5, wherein the power source stops applying a voltage to the target part when the magnet part reaches one of the approach points.

7. The method for controlling a magnetron sputtering device according to claim 5, wherein the magnet part has a plurality of magnets disposed with a prescribed gap therebetween in a movement direction of the magnet part.

8. The method for controlling a magnetron sputtering device according to claim 5, wherein the target part has a plurality of targets disposed with a prescribed gap therebetween in a movement direction of the magnet part.

9. A film forming method in which a film is formed on a substrate using a magnetron sputtering device that includes:
a substrate holding part that holds the substrate;
a target part disposed so as to face the substrate held by the substrate holding part;
a power source that supplies power to the target part;
a magnet part that is disposed on a rear side of the target part, the rear side being a side of the target part opposite to the substrate, the magnet part moving back and forth along the rear side of the target part; and
a chamber with electrically grounded side walls that stores the substrate holding part, the target part, the power source, and the magnet part therein,
the method comprising:
forming a thin film on a surface of the substrate by controlling the power source such that when the magnet part is away from approach points, the approach points being points closest to the side walls of the chamber, a prescribed voltage is applied from the power source to the target part, and when the magnet part reaches one of the approach points, the prescribed voltage is decreased.

10. The film forming method according to claim 9, wherein the power source stops applying a voltage to the target part when the magnet part reaches one of the approach points.

11. The film forming method according to claim 9, wherein the magnet part has a plurality of magnets disposed with a prescribed gap therebetween in a movement direction of the magnet part.

12. The film forming method according to claim 9, wherein the target part has a plurality of targets disposed with a prescribed gap therebetween in a movement direction of the magnet part.

13. The magnetron sputtering device according to claim 1, wherein the target part includes a target made of In—Ga—ZnO₄.

14. The method for controlling a magnetron sputtering device according to claim 5, wherein the target part includes a target made of In—Ga—ZnO₄.

15. The film forming method according to claim 9, wherein the target part includes a target made of In—Ga—ZnO₄.
